(19) United States
(12) Patent Application Publication
(10) Pub. No.: US 2023/0246620 A1
(43) Pub. Date: Aug. 3, 2023

(54) NOISE FILTER

(71) Applicant: Mitsubishi Electric Corporation, Tokyo (JP)

(72) Inventor: Kodai KATAGIRI, Tokyo (JP)

(73) Assignee: Mitsubishi Electric Corporation, Tokyo (JP)

(21) Appl. No.: 17/800,232

(22) PCT Filed: Apr. 9, 2020
(86) PCT No.: PCT/JP2020/015953

§ 371 Date: Aug. 17, 2022

(51) Int. Cl. H03H 7/01

(52) U.S. Cl. CPC H03H 7/0115

(57) ABSTRACT

A first path formed by a first capacitor connected in parallel with a noise generation source and a second path formed by a second capacitor connected in parallel with a load are arranged so as to be, at least partially, opposed to each other in a perpendicular direction, the first path and the second path are connected such that the first capacitor and the second capacitor are connected in parallel with each other, and the first path and the second path are arranged such that a direction of current flowing through the first path and a direction of induced current flowing when a magnetic flux generated by the current interlinks the second path are identical to each other at the first capacitor and the second capacitor.

### TECHNICAL FIELD

The present disclosure relates to a noise filter.

### BACKGROUND ART

As a noise filter for suppressing electromagnetic noise, a capacitor is generally used. When current flows through the capacitor itself or a wire connecting the capacitors, a magnetic flux is generated therearound. When the magnetic flux interlinks another wire or circuit, an apparent parasitic inductance increases due to magnetic coupling. For example, in a noise filter having a plurality of capacitors arranged in parallel, it is known that an electromagnetic noise reducing effect is deteriorated due to magnetic coupling occurring between the plurality of capacitors. Further, in a case where a plurality of capacitors are arranged closely to each other for the purpose of size reduction or the like, an interlinkage magnetic flux increases, thus causing a problem of further increasing the influence of magnetic coupling.

As means for solving this, for example, Patent Document 1 describes that wires between capacitors connected in parallel are crossed, thereby suppressing occurrence of magnetic coupling between the capacitors and reducing the parasitic inductance.

### CITATION LIST

### Patent Document

Patent Document 1: Japanese Patent No. 6113292 (page 8, lines 47 to 50; page 9, lines 1 to 9; FIG. 8)

### SUMMARY OF THE INVENTION

### Problems To Be Solved by the Invention

The configuration in Patent Document 1 can weaken magnetic coupling occurring between the capacitors, but has a problem of complicating the structure because wires are crossed.

The present disclosure has been made to solve the above problem, and an object of the present disclosure is to improve the electromagnetic noise reducing effect of a noise filter by reducing a parasitic inductance occurring due to magnetic coupling, without adopting such a complicated structure as to cross wires.

### Solution to the Problems

A noise filter according to the present disclosure includes: a first introduction portion and a second introduction portion connected to a noise generation source; a first capacitor connected to the first introduction portion and the second introduction portion in parallel with the noise generation source; a third introduction portion and a fourth introduction portion connected to a load; and a second capacitor connected to the third introduction portion and the fourth introduction portion in parallel with the load. A first path formed of the first introduction portion, the second introduction portion, and the first capacitor and a second path formed of the third introduction portion, the fourth introduction portion, and the second capacitor are arranged so as to be, at least partially, opposed to each other in a perpendicular direction. The first path and the second path are connected such that the first capacitor and the second capacitor are connected in parallel with each other. The first path and the second path are arranged such that a direction of current flowing through the first path and a direction of induced current flowing when a magnetic flux generated by the current interlinks the second path are identical to each other at the first capacitor and the second capacitor.

### Effect of the Invention

The noise filter according to the present disclosure makes it possible to improve the electromagnetic noise reducing effect without adopting such a complicated structure as to cross wires.

### BRIEF DESCRIPTION OF THE DRAWINGS

FIG. 1 schematically shows a circuit configuration of a noise filter in comparative example 1.

FIG. 2 shows an equivalent circuit of the noise filter in comparative example 1.

FIG. 3 shows an equivalent circuit of a noise filter in comparative example 2.

FIG. 4 schematically shows a circuit configuration of a noise filter according to embodiment 1.

FIG. 5 shows an equivalent circuit of the noise filter according to embodiment 1.

FIG. 6 shows an analysis result example of an electromagnetic noise reducing effect of the noise filter according to embodiment 1.

FIG. 7 schematically shows another circuit configuration of the noise filter according to embodiment 1.

FIG. 8 schematically shows another circuit configuration of the noise filter according to embodiment 1.

FIG. 9 schematically shows a circuit configuration of a noise filter according to embodiment 2.

FIG. 10 schematically shows a circuit configuration of a noise filter according to embodiment 3.

FIG. 11 schematically shows a circuit configuration of a noise filter according to embodiment 4.

FIG. 12 schematically shows a circuit configuration of a noise filter according to embodiment 5.

FIG. 13 schematically shows a circuit configuration of a noise filter according to embodiment 6.

### DESCRIPTION OF EMBODIMENTS

### Embodiment 1

Hereinafter, a preferred embodiment of a noise filter according to the present disclosure will be described with reference to the drawings. The same or corresponding matters or parts are denoted by the same reference characters and the detailed description thereof is omitted. Also in the other embodiments, components denoted by the same reference characters will not be repeatedly described.

### Description of Comparative Examples

Electromagnetic noises are roughly classified into normal mode noise and common mode noise by their propagation paths. The normal mode noise is also called differential mode noise, and is electromagnetic noise propagating between signal lines. The common mode noise is electromagnetic noise propagating between a signal line and a reference ground potential.

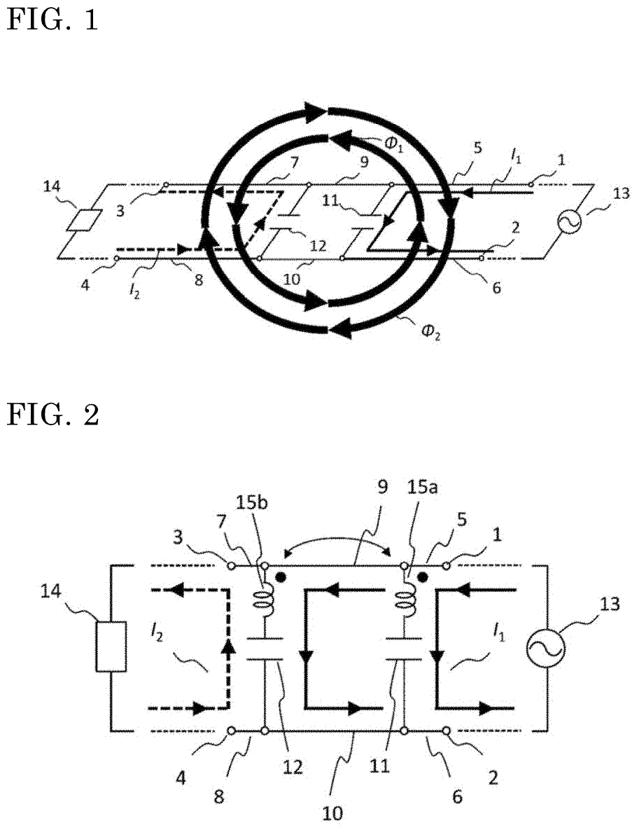

A circuit configuration in comparative example 1 shown in FIG. 1 is formed from a first introduction wire 5 having a first introduction end 1, a second introduction wire 6 having a second introduction end 2, a third introduction wire 7 having a third introduction end 3, a fourth introduction wire 8 having a fourth introduction end 4, a first connection wire 9 connecting the first introduction wire 5 and the third introduction wire 7, a second connection wire 10 connecting the second introduction wire 6 and the fourth introduction wire 8, and a capacitor group including a first capacitor 11 connected between the first introduction wire 5 and the second introduction wire 6, and a second capacitor 12 connected between the third introduction wire 7 and the fourth introduction wire 8. An electromagnetic noise generation source 13 is connected to the first introduction end 1 and the second introduction end 2, and a load 14 is connected to the third introduction end 3 and the fourth introduction end 4.

The first capacitor 11 and the second capacitor 12 are referred to as line-to-line capacitors. The line-to-line capacitors have a function of bypassing normal mode noise and thus inhibiting electromagnetic noise propagation to the load 14. Therefore, it is desirable that the impedance characteristics of the first capacitor 11 and the second capacitor 12 are small. However, at the capacitor itself or a wire connecting the capacitors, due to the physical structure thereof, an unintended inductance component (parasitic inductance) occurs in series to the capacitor. If the parasitic inductance is great, the bypass effect of the capacitor for electromagnetic noise is reduced. Further, when current flows through the capacitor itself or a wire connecting the capacitors, a magnetic flux is generated therearound. When the magnetic flux interlinks another wire or circuit, an apparent parasitic inductance increases due to magnetic coupling.

Therefore, as shown in FIG. 1, in the case where the first capacitor 11 and the second capacitor 12 are arranged in parallel closely to each other, when current I₁ flows through the first capacitor 11, a magnetic flux Φ₁ is generated. When the magnetic flux Φ₁ interlinks the second capacitor 12, a magnetic flux Φ₂ opposite to the magnetic flux Φ₁ is generated in accordance with the Lenz's law, so that induced current I₂ flows through the second capacitor 12. The induced current I₂ flows in a direction from the fourth introduction wire 8 through the second capacitor 12 to the third introduction wire 7, as shown by broken-line arrows in FIG. 1 or FIG. 2. Thus, the function of the second capacitor 12 for bypassing electromagnetic noise is reduced. In other words, it can be said that a parasitic inductance 15a of the first capacitor 11 and a parasitic inductance 15b of the second capacitor 12 are magnetically coupled with each other and thus the apparent parasitic inductance increases.

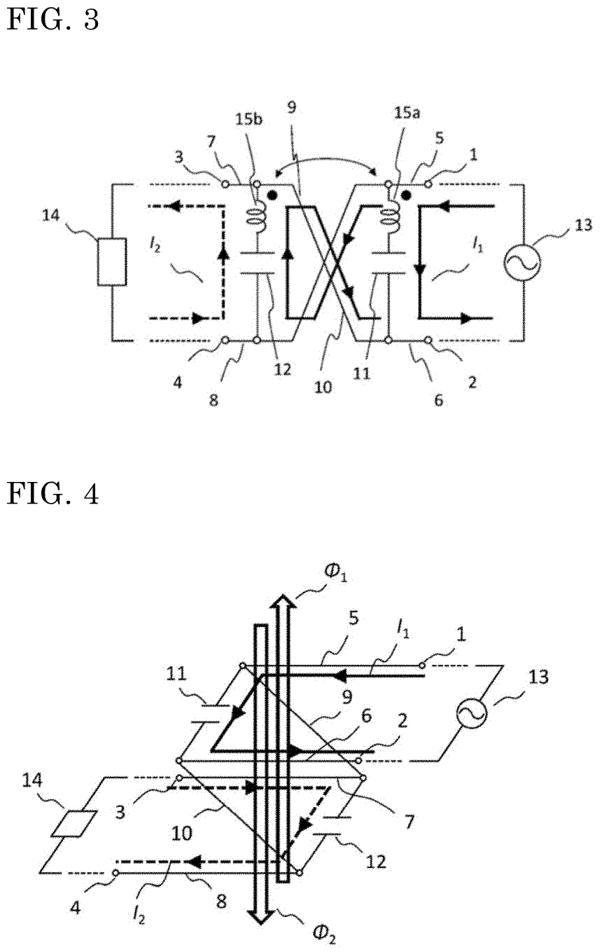

On the other hand, in a case of comparative example 2 as shown in FIG. 3, the first connection wire 9 and the second connection wire 10 are crossed, whereby occurrence of magnetic coupling between the capacitors is suppressed and the induced current I₂ is reduced. Thus, the parasitic inductances 15a, 15b can be reduced. However, the structure is complicated because the wires are crossed.

### Description of Configuration of Embodiment 1

FIG. 4 shows an example of a noise filter configuration of embodiment 1. A first path formed of the first introduction wire 5, the first capacitor 11, and the second introduction wire 6 and a second path formed of the third introduction wire 7, the second capacitor 12, and the fourth introduction wire 8 are, at least partially, opposed to each other in a direction perpendicular to their plane directions. Further, the first path and the second path are arranged such that the directions of the current I₁ flowing through the first path and the induced current I₂ flowing through the second path are identical to each other at the first capacitor 11 and the second capacitor 12. Here, the induced current I₂ is current flowing due to the magnetic flux Φ₂ generated in a direction opposite to the magnetic flux Φ1 in accordance with the Lenz's law when the magnetic flux Φ₁ generated by the current I₁ flowing through the first path interlinks the second path.

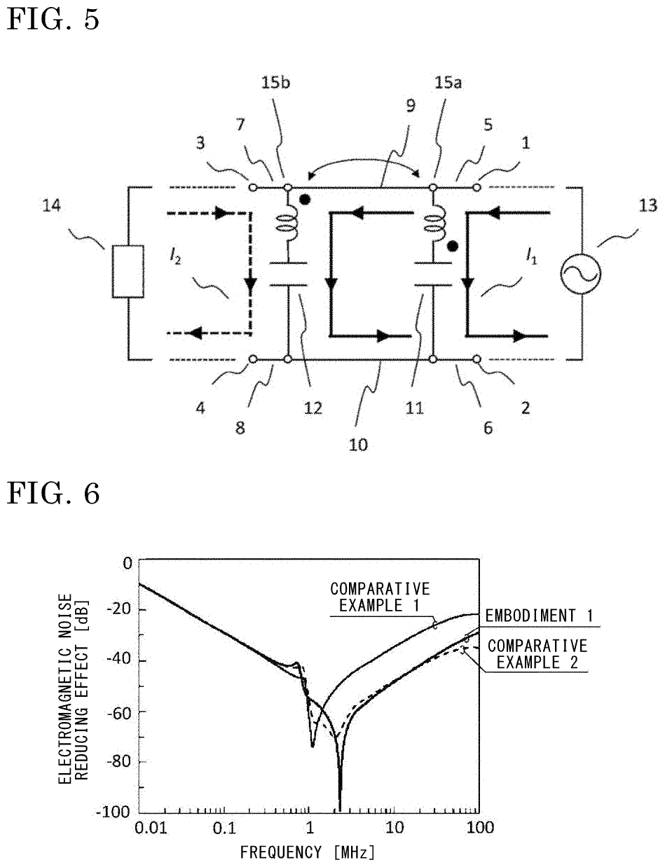

The induced current I₂ flows in a direction from the third introduction wire 7 through the second capacitor 12 to the fourth introduction wire 8. Therefore, as compared to the comparative example shown in FIG. 1 or FIG. 2, magnetic coupling occurs in directions opposite to each other as shown in FIG. 5. Thus, the parasitic inductance 15a of the first capacitor 11 and the parasitic inductance 15b of the second capacitor 12 are reduced. Accordingly, in this configuration, the parasitic inductance reducing effect increases as magnetic coupling between the first path and the second path is intensified. In the present embodiment, the first connection wire 9 and the second connection wire 10 are shown as straight lines. However, without limitation thereto, for example, they may be wires including curve lines or orthogonal parallel wires with respect to the planes respectively formed by the first path and the second path.

FIG. 6 shows an analysis result of the electromagnetic noise reducing effect. The configuration of embodiment 1 exhibits an electromagnetic noise reducing effect equal to or greater than that of the comparative example 2, and the electromagnetic noise reducing effect of embodiment 1 is greatly improved as compared to comparative example 1.

With the above configuration, the noise filter bypasses electromagnetic noise generated from the electromagnetic noise generation source 13 interposed between the first introduction end 1 and the second introduction end 2, by the first capacitor 11 and the second capacitor 12, and thus can inhibit propagation of electromagnetic noise to the load 14 interposed between the third introduction end 3 and the fourth introduction end 4.

In the present embodiment, the first introduction wire 5, the second introduction wire 6, the third introduction wire 7, the fourth introduction wire 8, the first connection wire 9, and the second connection wire 10 are provided as wires. However, they may be provided as a pattern on a printed board, or a busbar.

The electromagnetic noise generation source is provided between the first introduction end 1 and the second introduction end 2, and the load 14 is provided between the third introduction end 3 and the fourth introduction end 4. However, without limitation thereto, the load 14 may be provided between the first introduction end 1 and the second introduction end 2, and the electromagnetic noise generation source 13 may be provided between the third introduction end 3 and the fourth introduction end 4. In the present embodiment, the electromagnetic noise generation source 13 is shown by a circuit symbol of an AC power supply. However, without limitation thereto, the electromagnetic noise generation source 13 may be any source that generates electromagnetic noise due to a high-frequency signal unnecessary for supply of power to devices or a control signal. Examples of the electromagnetic noise generation source 13 include an inverter/converter that performs power conversion using switching elements, a microcomputer, and an integrated circuit such as an application specific integrated circuit (ASIC).

The load 14 represents a device connected to the electromagnetic noise generation source 13 and is shown as a resistance element in the present embodiment, but is not limited thereto. That is, the load 14 may be any device connected to the electromagnetic noise generation source 13, such as a grid power supply, a battery, a circuit needed for supplying power or a control signal, or a load such as a motor.

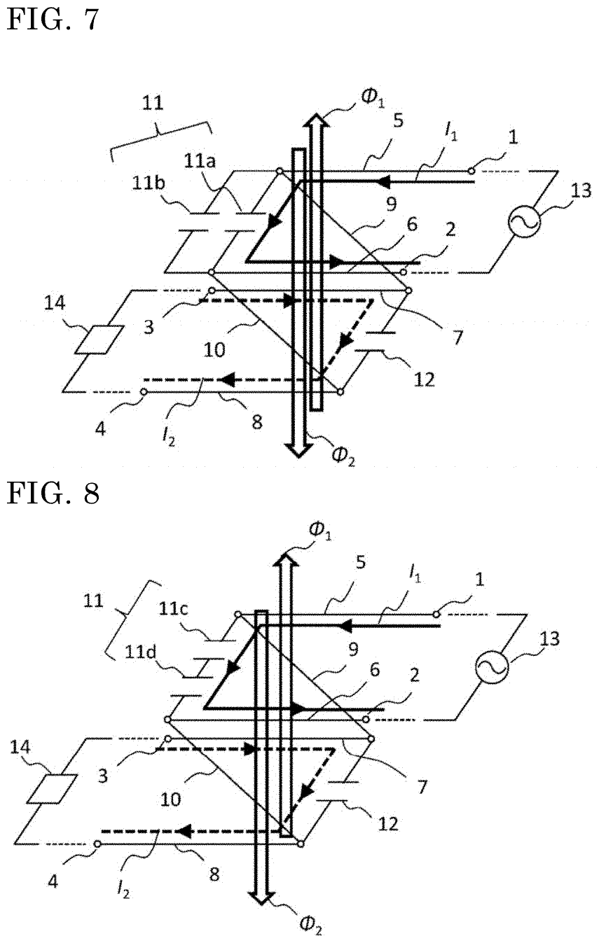

At least one of the first capacitor 11 and the second capacitor 12 may be composed of a plurality of elements. For example, as shown in FIG. 7, the first capacitor 11 may be composed of two capacitors that are a capacitor 11a and a capacitor 11b connected in parallel, or as shown in FIG. 8, the first capacitor 11 may be composed of two capacitors that are a capacitor 11c and a capacitor 11d connected in series. Alternatively, series connection and parallel connection may be combined.

As described above, according to the present embodiment, the first path including the first capacitor 11 and the second path including the second capacitor 12 are arranged so as to be, at least partially, opposed to each other, and such that the directions of the current I₁ flowing through the first path and the induced current I₂ flowing through the second path are identical to each other at the first capacitor 11 and the second capacitor 12. Thus, magnetic coupling between the first capacitor 11 and the second capacitor 12 is made in directions opposite to each other, whereby the parasitic inductance 15a of the first capacitor 11 and the parasitic inductance 15b of the second capacitor 12 are reduced, normal mode noise is bypassed without adopting such a complicated structure as to cross wires as in comparative example 2, and the electromagnetic noise reducing effect of the noise filter can be improved.

### Embodiment 2

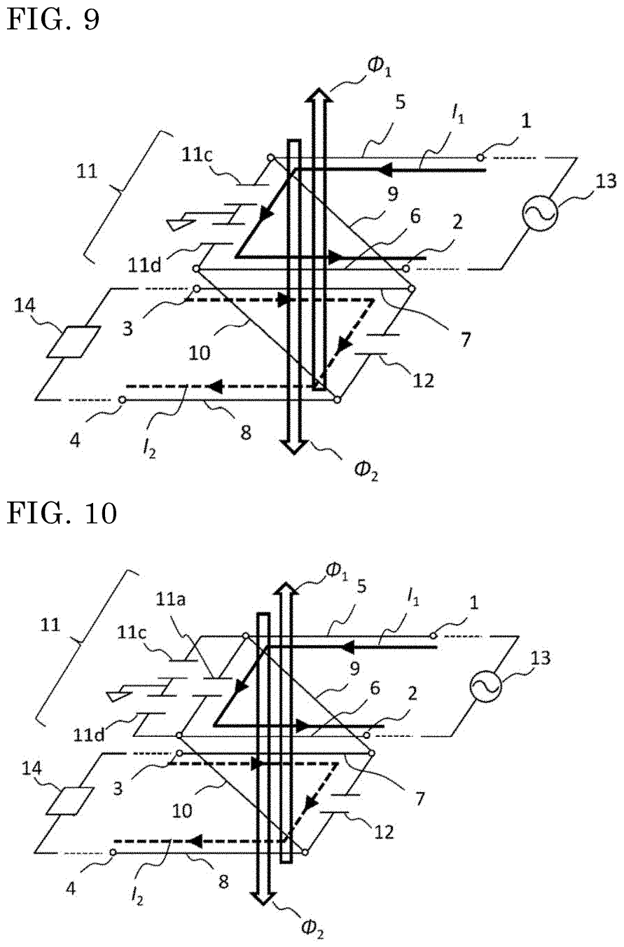

FIG. 9 shows a noise filter example in which a capacitor 11c and a capacitor 11d forming the first capacitor 11 in the noise filter shown in FIG. 1 are formed as capacitors to ground. The capacitor to ground is a capacitor interposed between a signal line and a reference ground potential. The capacitor 11c is connected between the first introduction wire 5 and the reference ground potential, the capacitor 11d is connected between the second introduction wire 6 and the reference ground potential, and these capacitors have a function of bypassing common mode noise and thus inhibiting electromagnetic noise propagation to the load 14. In FIG. 9, the first capacitor 11 is formed as a capacitor to ground, but at least one of the first capacitor 11 and the second capacitor 12 may be formed as a capacitor to ground.

With this configuration, as in embodiment 1, magnetic coupling between the first capacitor 11 and the second capacitor 12 is made in directions opposite to each other, and thus the parasitic inductance 15a of the first capacitor 11 and the parasitic inductance 15b of the second capacitor 12 are reduced, whereby normal mode noise can be bypassed. Further, since at least one of the first capacitor 11 and the second capacitor 12 is formed as a capacitor to ground, common mode noise can also be reduced, and thus the electromagnetic noise reducing effect of the noise filter can be more improved.

### Embodiment 3

In FIG. 10, the capacitor 11a is connected in parallel with the capacitor 11c and the capacitor 11d forming the capacitors to ground shown in FIG. 9, thus forming the first capacitor 11. Although a capacitor to ground is formed in the first capacitor 11 in FIG. 10, a capacitor to ground may be formed in at least one of the first capacitor 11 and the second capacitor 12.

With this configuration, as in embodiment 2, magnetic coupling between the first capacitor 11 and the second capacitor 12 is made in directions opposite to each other and thus the parasitic inductance 15a of the first capacitor 11 and the parasitic inductance 15b of the second capacitor 12 are reduced, whereby normal mode noise can be bypassed. In addition, since the capacitor 11c and the capacitor 11d forming the first capacitor 11 are capacitors to ground, common mode noise can also be reduced, whereby the electromagnetic noise reducing effect of the noise filter can be more improved. Since the capacitor 11a is connected in parallel with the capacitor 11c and the capacitor 11d, normal mode noise can be more bypassed than in embodiment 2. Although the case of the first capacitor 11 has been described, the same effects are provided if a capacitor to ground is formed in at least one of the first capacitor 11 and the second capacitor 12.

### Embodiment 4

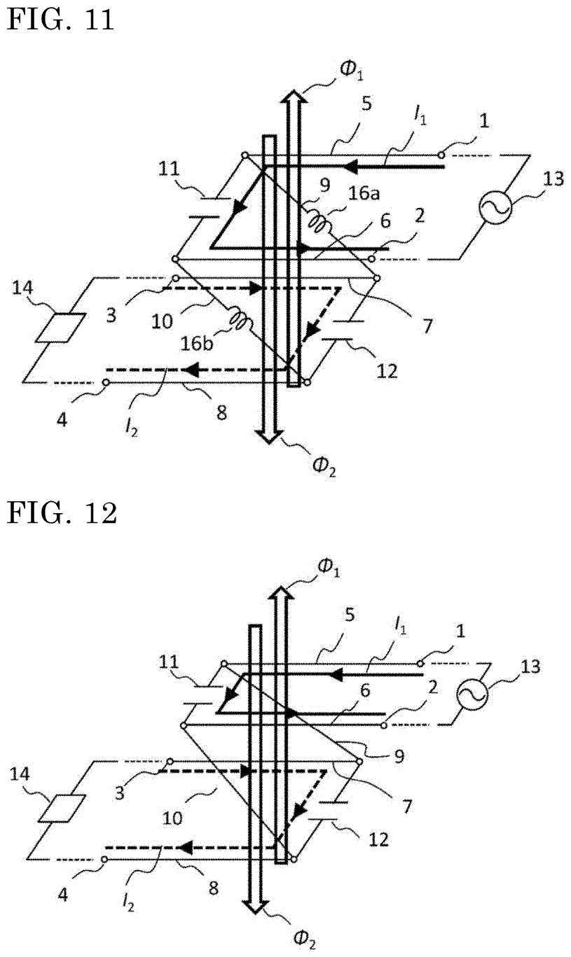

FIG. 11 shows an example in which an inductor 16a is interposed on the first connection wire 9 and an inductor 16b is interposed on the second connection wire 10 in the noise filter shown in embodiment 1. With this configuration, magnetic coupling between the first capacitor 11 and the second capacitor 12 is made in directions opposite to each other and thus the parasitic inductance 15a of the first capacitor 11 and the parasitic inductance 15b of the second capacitor 12 are reduced, whereby normal mode noise can be bypassed. Further, the inductors 16a, 16b and the first capacitor 11 or the second capacitor 12 form an LC filter, whereby high-frequency noise can be removed. In the present embodiment, the inductors 16a, 16b are interposed on both of the first connection wire 9 and the second connection wire 10, but the inductor may be interposed on one of the first connection wire 9 and the second connection wire 10. In the above description, the case where the inductors 16a, 16b are inductor elements has been shown. However, without limitation thereto, they may be other parts such as a cable or a busbar in which an inductive component is dominant. At least one of the inductors 16a, 16b may be composed of a plurality of elements.

### Embodiment 5

FIG. 12 shows an example in which, at a part where the first path and the second path composing the noise filter in embodiment 1 are opposed to each other, the first path is, at least partially, located on the inner peripheral side of the second path. Also with this configuration, the same effects as in the noise filter shown in embodiment 1 can be obtained. Further, with this configuration, a larger amount of the magnetic flux Φ1 generated by the current I1 flowing through the first path interlinks the second path, whereby magnetic coupling between the first path and the second path can be more intensified.

### Embodiment 6

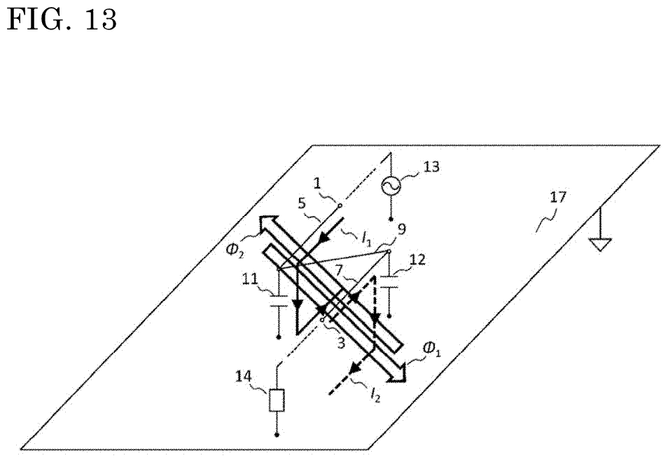

FIG. 13 shows a specific example of a noise filter configuration in which the second introduction wire 6, the fourth introduction wire 8, and the second connection wire 10 composing the noise filter in embodiment 1 are formed as a ground potential 17. The ground potential refers to a ground pattern on a printed board or a housing, for example. Also with this configuration, the same effects as in the noise filter shown in embodiment 1 can be obtained.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

1 first introduction end

2 second introduction end

3 third introduction end

4 fourth introduction end

5 first introduction wire

6 second introduction wire

7 third introduction wire

8 fourth introduction wire

9 first connection wire

10 second connection wire

11 first capacitor

12 second capacitor

13 electromagnetic noise generation source

14 load

15a, 15b parasitic inductance

16a, 16b inductor

17 ground potential

1.-6. (canceled)

7. A noise filter comprising:
a first introduction portion and a second introduction portion connected to a noise generation source;
a first capacitor connected to the first introduction portion and the second introduction portion in parallel with the noise generation source;
a third introduction portion and a fourth introduction portion connected to a load; and
a second capacitor connected to the third introduction portion and the fourth introduction portion in parallel with the load, wherein
a first path through which the first introduction portion, the second introduction portion, and the first capacitor are connected and a second path through which the third introduction portion, the fourth introduction portion, and the second capacitor are connected are arranged so as to be, at least partially, opposed to each other in a perpendicular direction,
the first path and the second path are connected such that the first capacitor and the second capacitor are connected in parallel with each other, and
the first path and the second path are arranged such that a direction of current flowing through the first path and a direction of induced current flowing when a magnetic flux generated by the current interlinks the second path are identical to each other at the first capacitor and the second capacitor.

8. A noise filter comprising:
a first introduction portion and a second introduction portion connected to a noise generation source;
a first capacitor connected to the first introduction portion and the second introduction portion in parallel with the noise generation source;
a third introduction portion and a fourth introduction portion connected to a load; and
a second capacitor connected to the third introduction portion and the fourth introduction portion in parallel with the load, wherein
a first path formed of the first introduction portion, the second introduction portion, and the first capacitor and a second path formed of the third introduction portion, the fourth introduction portion, and the second capacitor are arranged so as to be, at least partially, opposed to each other in a perpendicular direction,
the first path and the second path are connected such that the first capacitor and the second capacitor are connected in parallel with each other,
the first path and the second path are arranged such that a direction of current flowing through the first path and a direction of induced current flowing when a magnetic flux generated by the current interlinks the second path are identical to each other at the first capacitor and the second capacitor, and
at a part where the first path and the second path are opposed to each other, the first path is located on an inner side of the second path.

9. A noise filter comprising:
a first introduction portion and a second introduction portion connected to a noise generation source;
a first capacitor connected to the first introduction portion and the second introduction portion in parallel with the noise generation source;
a third introduction portion and a fourth introduction portion connected to a load; and
a second capacitor connected to the third introduction portion and the fourth introduction portion in parallel with the load, wherein
a first path formed of the first introduction portion, the second introduction portion, and the first capacitor and a second path formed of the third introduction portion, the fourth introduction portion, and the second capacitor are arranged so as to be, at least partially, opposed to each other in a perpendicular direction,
the first path and the second path are connected such that the first capacitor and the second capacitor are connected in parallel with each other,
the first path and the second path are arranged such that a direction of current flowing through the first path and a direction of induced current flowing when a magnetic flux generated by the current interlinks the second path are identical to each other at the first capacitor and the second capacitor, and
the first introduction portion, the third introduction portion, and a connection part between the first path and the second path, which serve as a current path from the noise generation source to the load, are formed as a ground potential.

10. The noise filter according to claim 7, wherein
at least one of the first capacitor and the second capacitor includes a capacitor to ground.

11. The noise filter according to claim 7, wherein
at least one of the first capacitor and the second capacitor includes a combination of a line-to-line capacitor and a capacitor to ground.

12. The noise filter according to claim 7, wherein
at a part where the first path and the second path are opposed to each other, the first path is located on an inner side of the second path.

13. The noise filter according to claim 7, wherein
an inductor is interposed at a connection part between the first path and the second path.

14. The noise filter according to claim 7, wherein
the first introduction portion, the third introduction portion, and a connection part between the first path and the second path, which serve as a current path from the noise generation source to the load, are formed as a ground potential.

15. The noise filter according to claim 8, wherein
at least one of the first capacitor and the second capacitor includes a capacitor to ground.

16. The noise filter according to claim 9, wherein
at least one of the first capacitor and the second capacitor includes a capacitor to ground.

17. The noise filter according to claim 8, wherein
at least one of the first capacitor and the second capacitor includes a combination of a line-to-line capacitor and a capacitor to ground.

18. The noise filter according to claim 9, wherein
at least one of the first capacitor and the second capacitor includes a combination of a line-to-line capacitor and a capacitor to ground.

19. The noise filter according to claim 8, wherein
at a part where the first path and the second path are opposed to each other, the first path is located on an inner side of the second path.

20. The noise filter according to claim 9, wherein
the first introduction portion, the third introduction portion, and a connection part between the first path and the second path, which serve as a current path from the noise generation source to the load, are formed as a ground potential.

21. The noise filter according to claim 10, wherein
an inductor is interposed at a connection part between the first path and the second path.

22. The noise filter according to claim 11, wherein
an inductor is interposed at a connection part between the first path and the second path.

23. The noise filter according to claim 12, wherein
an inductor is interposed at a connection part between the first path and the second path.

24. The noise filter according to claim 13, wherein
an inductor is interposed at a connection part between the first path and the second path.

25. The noise filter according to claim 14, wherein
an inductor is interposed at a connection part between the first path and the second path.
